(19) United States
(12) Patent Application Publication
(10) Pub. No.: US 2020/0295083 A1
(43) Pub. Date: Sep. 17, 2020

(54) BARRIER LAYER FOR SELECTOR DEVICES AND MEMORY DEVICES USING SAME

(71) Applicants: MACRONIX INTERNATIONAL CO., LTD., HSINCHU (TW); INTERNATIONAL BUSINESS MACHINES CORPORATION, ARMONK, NY (US)

(72) Inventors: Huai-Yu CHENG, WHITE PLAINS, NY (US); I-Ting KUO, TAOYUAN (TW); Hsiang-Lan LUNG, ARDSLEY, NY (US); Robert L. Bruce, WHITE PLAINS, NY (US); Fabio Carta, Pleasantville, NY (US)

(73) Assignees: MACRONIX INTERNATIONAL CO., LTD., HSINCHU (TW); INTERNATIONAL BUSINESS MACHINES CORPORATION, ARMONK, NY (US)

(21) Appl. No.: 16/355,292

(22) Filed: Mar. 15, 2019

(51) Int. Cl. H01L 27/24; H01L 45/00

(52) U.S. Cl. CPC H01L 27/2427; H01L 45/1608; H01L 45/06; H01L 27/2463

(57) ABSTRACT

A voltage sensitive switching device has a first electrode, a second electrode, and a switching layer between the first and second electrodes. An in situ barrier layer is disposed between the first and second electrodes. The barrier layer comprises a composition including silicon and carbon. The switching device can be used in memory devices, including 3D cross-point memory.

International Business Machines Corporation, a New York corporation, and Macronix International Corporation, Ltd., a Taiwan corporation, are parties to a Joint Research Agreement.

### BACKGROUND

### Field

The present invention relates to switching devices utilized in integrated circuits, including integrated circuit memory devices.

### Description of Related Art

There are many applications for switching devices, such as transistors and diodes, in integrated circuits. One type of switching device is known as the ovonic threshold switch, based on ovonic materials, characterized by a large drop in resistance at a switching threshold voltage, and recovery of a high resistance, blocking state when the voltage falls below a holding threshold.

Switching devices have been used, for example, in various programmable resistance memory devices comprising high density arrays of cells organized in a cross-point architecture. Some cross-point architectures utilize memory cells that include a phase change memory element in series with an ovonic threshold switch (OTS), for example. Other architectures are utilized, including a variety of 2-dimensional and 3-dimensional array structures, which can also utilize switching devices to select memory elements in the array. Also, ovonic threshold switches have been proposed for a variety of other uses, including so called neuromorphic computing.

A problem associated with manufacturing devices including OTS selectors arises because the OTS materials are easily oxidized in many settings. One option to address this oxidation involves in situ formation of a capping layer, such as pure carbon (e.g. amorphous carbon or other carbon phases) or nitrogen-doped carbon, to reduce oxidation of the OTS material. However, even with these techniques, oxidation of the OTS can remain a significant problem.

It is desirable to provide an improved technology to reduce oxidation of OTS materials during manufacturing.

### SUMMARY

A switch device is described comprising a first electrode, a second electrode, and a switching layer between the first and second electrodes. The switching layer can comprise an OTS material. A barrier layer is disposed on a surface of the switching layer, and comprises a composition including silicon and carbon. Carbon can have a greater concentration in the composition than silicon (silicon doped carbon). In embodiments described herein, silicon in the composition can have a concentration in a range of about 4 to 18 atomic percent. The barrier layer can comprise an in situ deposited layer, comprising silicon and carbon.

A memory device is described that includes a first electrode, a second electrode, a memory element such as a phase change memory material or other programmable resistance memory material, in contact with the first electrode, and a switching layer in series with the memory element between the first and second electrodes. The memory device can include a barrier layer between the memory element and the switching layer. The barrier layer comprises a composition including silicon and carbon, as described herein.

The memory device can be configured as a 3D cross-point memory on an integrated circuit device, having very high density.

Also the switching device can be utilized in a variety of other kinds of devices.

Manufacturing methods for the device are described. The barrier layer can be in situ deposited with the ovonic threshold switch material.

Use of the barrier layer as described herein can improve thermal stability and reduce oxidation of the underlying OTS material. An OTS switch including a silicon doped carbon barrier layer can survive high temperature annealing.

Other aspects and advantages of the present invention can be seen on review of the drawings, the detailed description and the claims, which follow.

### BRIEF DESCRIPTION OF THE DRAWINGS

FIG. 1 is a simplified cross-section of a switching device including a barrier layer of a composition comprising silicon and carbon.

FIG. 2 is a graph plotting resistivity versus temperature showing testing results for barrier materials.

FIG. 3 is a simplified 3D perspective of a memory cell in a cross-point memory device including a switching device having a barrier layer as described herein.

FIG. 4 is a simplified 3D perspective of a switching device having a barrier layer as described herein in a cross-point configuration as described herein.

FIG. 5 is a simplified flowchart for manufacturing a memory device as described herein.

FIG. 6 is a simplified block diagram of an integrated circuit memory device comprising a 3D memory utilizing switching devices as described herein.

### DETAILED DESCRIPTION

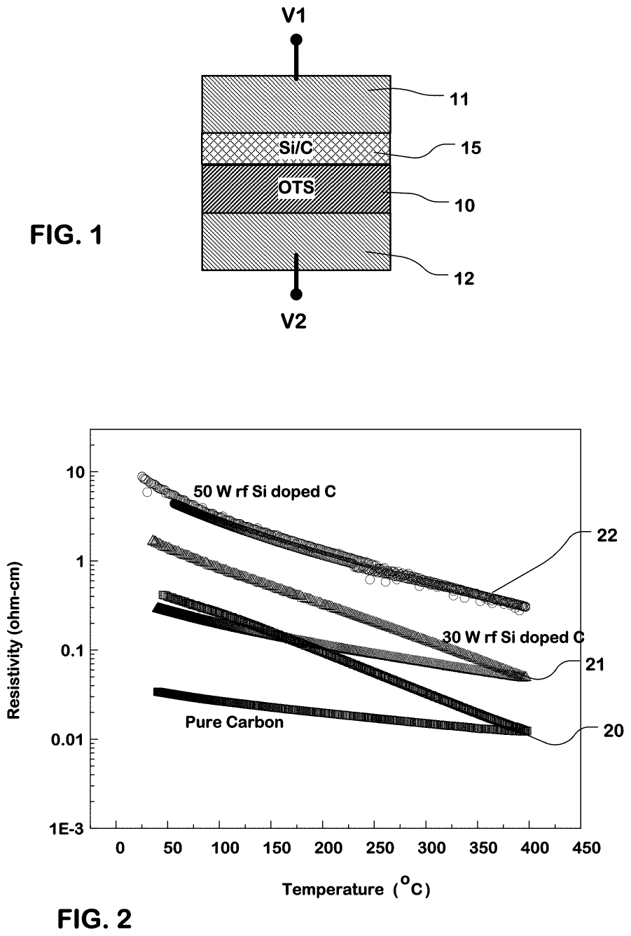

A detailed description of embodiments of the present invention is provided with reference to the FIGS. 1-6.

FIG. 1 is a simplified diagram of a switching device that includes a switching layer 10 of an ovonic threshold switch material with a barrier layer 15 as described herein. The barrier layer 15 is a composition including silicon and carbon on a top surface of the ovonic threshold switch material. The switching device includes a first electrode 11 and a second electrode 12, with the switching layer 10 in series between the first electrode 11 and the second electrode 12. The barrier layer 15 contacts a surface of the ovonic threshold switch material, and can prevent or reduce oxidation of the material during manufacturing. A voltage V1 can be applied to the first electrode 11, and a voltage V2 can be applied to the second electrode 12. A second barrier layer can be disposed on a second surface (e.g., bottom surface) opposite said first mentioned surface, of the ovonic threshold switch material, in some embodiments.

In embodiments of the technology, the barrier layer 15 can comprise a combination of silicon and carbon, wherein the carbon has a higher concentration, measured in atomic percent, than the silicon. In combination with some ovonic switch materials, the barrier layer 15 can comprise a composition of silicon and carbon, in which the silicon has a concentration in a range of 4 to 18 atomic percent, or in a range of about 4 to 18 atomic percent. The barrier layer 15 can comprise an in situ barrier layer, deposited on the ovonic threshold switch material in the same chamber of the manufacturing line utilized for deposition of the ovonic threshold switch material.

The barrier layer 15 can comprise a composition that consists essentially of silicon and carbon in embodiments of the technology, such as in the case that the barrier layer 15 is formed by depositing only silicon and carbon, such as by co-sputtering in a common chamber with the switching material, with any impurities arising from contact with the switching material and the manufacturing procedures of subsequent layers.

FIG. 2 is a graph of resistivity versus temperature for materials which can be used as barrier layers with ovonic threshold switch material, where the temperature of the material is ramped from about 50° C. and about 400° C., and then allowed to cool back to about 50° C. The graph includes a first trace 20 showing the resistivity versus temperature of pure carbon. Pure carbon shows a substantial change in resistivity as a result of this thermal cycling.

The graph includes a second trace 21 showing the resistivity versus temperature of a combination of silicon and carbon, in which the silicon has a concentration of about 11.1 atomic percent and the carbon has a concentration of about 88.9 atomic percent. It can be seen that the resistivity is slightly higher, but the change in resistivity as a result of the thermal cycling is reduced significantly. This embodiment of the barrier material can be formed by sputtering of Si—C with RF power set at 30 W.

The graph includes a third trace 22 showing resistivity versus temperature of the combination of silicon and carbon, in which the silicon has a concentration of about 17.2 atomic percent, and the carbon has a concentration of about 82.8 atomic percent. In this embodiment, there is very little change in resistivity as a result of the thermal cycling. In effect, the resistivity returns to its initial value even after annealing to 400° C. This embodiment of the barrier material can be formed by sputtering of Si—C with RF power set at 50 W.

In addition, samples comprising ovonic threshold switch material capped with a barrier material comprising silicon and carbon, and samples comprising ovonic threshold switch material with the barrier material consisting of pure carbon, were subject to annealing to test thermal stability of the ovonic threshold switch. It is found that the samples utilizing a barrier material comprising of silicon and carbon survived annealing at 400° C., while samples utilizing pure carbon were significantly damaged.

Additional testing was carried out using an ovonic threshold switch material comprising As, in which outgassing of AsH3 is an indicator of oxidation of the ovonic threshold switch material. In the tested example, the ovonic threshold switch material comprised AsSeGeSi. This additional testing measured AsH3 outgassing for a sample having a barrier layer 60 nm thick of pure carbon, and for a sample having a barrier layer 60 nm thick of a combination of silicon and carbon as described herein. AsH3 outgassing signals that the As-containing film is reacting with moisture, which can cause oxidation. It is found that the outgassing is substantially reduced in the example using a combination of silicon and carbon.

Also, the oxygen content of the ovonic threshold switch material was compared in the samples. In samples utilizing a pure carbon barrier layer, oxygen can have a concentration of greater than 20 at %. In the sample utilizing a combination of silicon and carbon as the barrier layer, oxygen was found at a concentration of about 4.5 at %.

This testing demonstrates that a barrier layer comprising a combination of silicon and carbon exhibits good capping of capability. Utilizing barrier layers as described herein can essentially stop oxidation of the OTS material. Also, barrier layers as described herein have greater stability in resistivity over wide temperature ranges. Furthermore, barrier layers as described herein, combined with ovonic threshold switch material, are operable at high temperatures without damage.

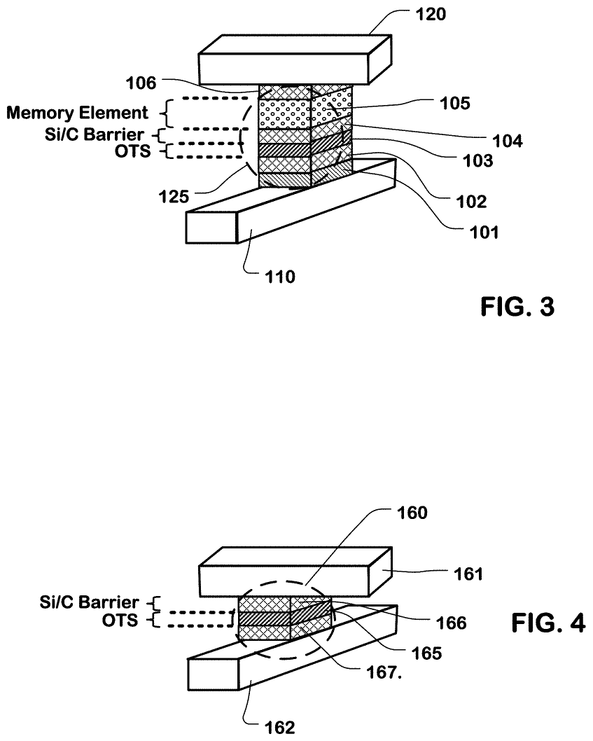

FIG. 3 illustrates an example memory cell 125 which comprises a multi-layer pillar disposed in the cross-point of a first access line 110 and a second access line 120.

The pillar in this example includes a bottom electrode layer 101, such as a metal, metal nitride, a doped semiconductor, or the like, on the first access line 110.

A buffer layer 102 disposed on the bottom electrode layer 101. In some embodiments, the buffer layer 102 comprises a composition as silicon and carbon as described herein. The buffer layer 102 can be for example, 15 to 30 nm thick.

An OTS switching layer 103 is disposed on the buffer layer 102. The OTS switching layer 103 can comprise an OTS material such as, for example, AsSeGeSi, AsSeGeSiC, AsSeGeSiN, AsSeGeSiTe, AsSeGeSiTeS, AsTeGeSi, AsTeGeSiN, and other available OTS materials. In some embodiments of the technology, the OTS material comprises As. The OTS switching layer can be for example, 15 to 45 nm thick, and preferably less than 50 nm thick.

A buffer layer 104 is disposed on the OTS switching layer 103, and can be called a capping layer for the OTS material. The buffer layer 104 is a barrier layer that comprises a composition of silicon and carbon as discussed herein. In a preferred embodiment, the buffer layer 104 comprises a barrier layer including an in situ composition of silicon and carbon, in which the carbon has a higher concentration than the silicon. With some OTS materials, buffer layer 104 is a barrier layer including a composition of silicon and carbon, in which the silicon has a concentration in a range of 4 to 18 atomic percent. The buffer layer 104 can be for example, 15 to 30 nm thick.

A memory material layer 105 is disposed on the buffer layer 104. The memory material can comprise a programmable resistance material. In embodiments of the technology, the memory material comprises a phase change memory material, such as

GST (e.g., Ge2Sb2Te5), silicon oxide doped GST, nitrogen doped GST, silicon oxide doped GaSbGe, or other phase change memory materials. In some embodiments, other programmable resistance memory elements can be implemented, such as metal-oxide resistive memories, magnetic resistive memories and conducting-bridge resistive memories, or other types of memory devices. The memory material layer 105 can have a thickness selected according to the particular material utilized. For phase change material, an example range of thicknesses can be 5 to 50 nm thick.

A top buffer layer 106 is disposed on the memory material layer 105. In some embodiments, the top buffer layer 106 comprises a composition including silicon and carbon as described herein. The top buffer layer 106 can be, for example, 15 to 30 nm thick.

Example materials, other than a combination of silicon and carbon as described herein, for the first buffer layer 102 and the top buffer layer 106 can be a metal nitride, such as titanium nitride (TiN), tantalum nitride (TaN), tungsten nitride (WN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (WAlN), tantalum silicon nitride (TaSiN), tantalum aluminum nitride (TaAlN). In addition to metal nitrides, the first buffer layer 102 and the top buffer layer 106 can comprise materials such as carbon, doped polysilicon, tungsten (W), copper (Cu), titanium (Ti), molybdenum (Mo), tantalum (Ta), titanium silicide (TiSi), tantalum silicide (TaSi), titanium tungsten (TiW), titanium oxynitride (TiON), titanium aluminum oxynitride (TiAlON), tungsten oxynitride (WON), and tantalum oxynitride (TaON).

The memory element 125 can comprise a layer of programmable resistance material. In one example, the memory element 125 comprises a phase change memory material.

The first access lines (bit lines) and the second access lines (word lines) can comprise a variety of metals, metal-like materials and doped semiconductors, or combinations thereof. Embodiments of the first and second access lines can be implemented using one or more layers of materials like tungsten (W), aluminum (Al), copper (Cu), titanium nitride (TiN), tantalum nitride (TaN), tungsten nitride (WN), doped polysilicon, cobalt silicide (CoSi), Tungsten silicide (WSi), TiN/W/TiN, and other materials. For example, the thicknesses of the first access lines and the second access lines can range from 10 to 100 nm. In other embodiments, the first access lines and the second access lines can be very thin, or much thicker. The material selected for the second access lines is preferably selected for compatibility with the top buffer layer 106 in this example, or otherwise with the memory element 125. Likewise, the material selected for the first access lines is preferably selected for compatibility with the electrode material 101, or otherwise with the memory element 125.

In another embodiment, a bottom electrode layer like that shown in FIG. 3, has a smaller contact surface than the surface of the switching layer. As such, an increased current density can be achieved.

FIG. 4 illustrates an example switching cell 160 disposed in the cross-point of a first access line 161, and a second access line 162. The switching cell 160 is disposed in series between the first access line 161 and the second access line 162. The switching cell 160 includes a switching layer 165, disposed between the first buffer layer 166 and a second buffer layer 167. The switching layer 165 can comprise an As-containing OTS material or other OTS material. At least one of the buffer layer 165 and the buffer layer 166 comprises a composition of silicon and carbon as described herein. Representative materials of the other of the buffer layers 166, 167 can be the same as those discussed above.

For the switching devices of FIG. 1, FIG. 3 and FIG. 4, when the voltage (V1-V2) across the first electrode (e.g. 11) and the second electrode (e.g. 12) exceeds a threshold voltage of the switching layer, then the switching device is turned on. When the voltage across the first electrode and the second electrode is below a holding threshold voltage of the switching layer, and the switching device returns to a high impedance, off, state. The switching devices can have a highly nonlinear current versus voltage characteristic, making them suitable for use as a switching element in a high density memory device, and in other settings.

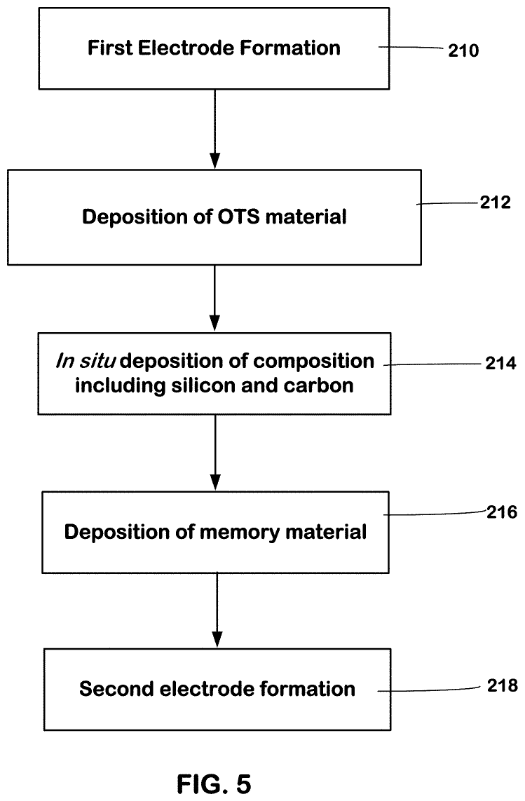

FIG. 5 is a simplified flow chart of a manufacturing process for manufacturing a memory device like that shown in FIG. 3. At step 210, the first electrode is formed on a substrate, and may extend through the dielectric layer to underlying circuits, or may be a patterned access line such as in a 3D cross-point array. As an example, the first electrode can comprise TiN and the dielectric layer can comprise SiN. The underlying circuitry or patterned access lines can be formed by standard processes as known in the art, and the configuration of elements of the circuitry depends upon the configuration in which the switching devices described herein are implemented. Generally, the circuitry may include access devices such as transistors, diodes, ovonic threshold switches, bit lines, word lines and source lines, conductive plugs, and doped regions within a semiconductor substrate.

The first electrode and the dielectric layer can be formed, for example, using methods, materials, and processes as disclosed in U.S. Pat. No. 8,138,028 entitled “Method for Manufacturing a Phase Change Memory Device with Pillar Bottom Electrode”, which is incorporated by reference herein.

Alternatively, the switching devices can be organized in a cross-point architecture, such as described in U.S. Pat. No. 6,579,760, entitled SELF-ALIGNED, PROGRAMMABLE PHASE CHANGE MEMORY, issued 17 Jun. 2003, which is incorporated by reference herein. The first electrode can be the access lines, such as word lines and/or bit lines. In such architecture, the access devices are arranged between the switching devices and the access lines.

At step 212, a switching layer including an OTS material, including materials described above, for example, is formed in a sputtering chamber of a sputtering system.

At step 214, deposition of a buffer layer including a composition of silicon and carbon as described above is formed, so that it acts as a barrier layer against oxidation of the switching layer. In a preferred example, the composition is formed by in situ sputtering in the same sputtering chamber as the OTS material, or otherwise formed without exposure of the OTS material to an oxidizing atmosphere.

At step 216, a memory material is formed on the buffer layer. The memory material can be a programmable resistance material, like a phase change material, or other materials as described above.

At step 218, a second electrode is formed. The second electrode can be formed by deposition and patterned etch, for example, of a conductive material.

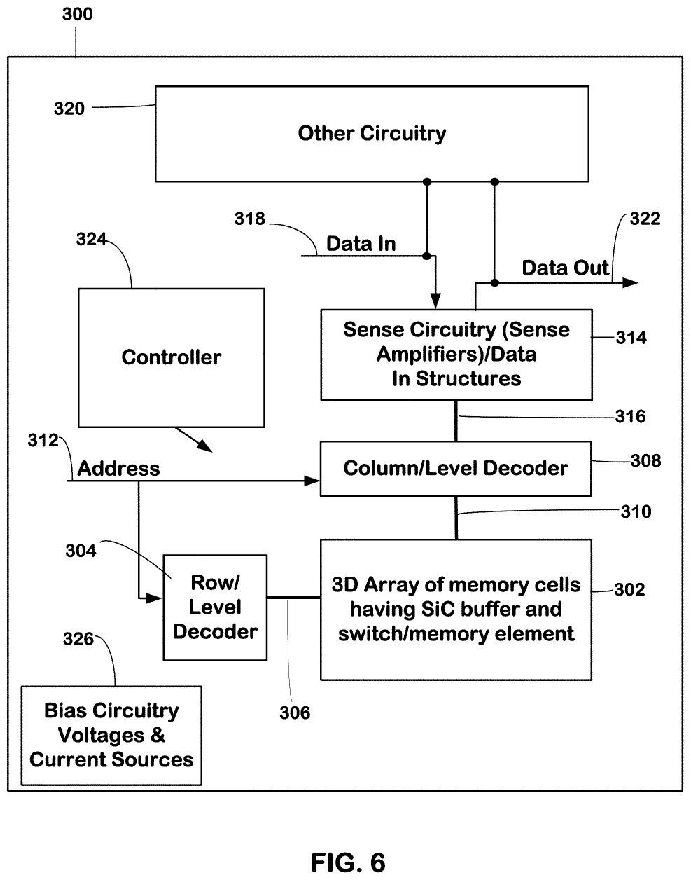

A device can be completed using back-end-of-line (BEOL) processing. The BEOL process is to complete the semiconductor process steps of the chip, resulting in the structure illustrated in FIG. 6. The BEOL processes can be standard processes as known in the art, and the processes performed depend upon the configuration of the chip in which the switching device is implemented. Generally, the structures formed by BEOL processes may include contacts, inter-layer dielectrics and various metal layers for interconnections on the chip, including circuitry to couple the switching device to peripheral circuitry. As a result of these processes, control circuits and biasing circuits as shown in FIG. 6 are formed on the device.

FIG. 6 is a simplified block diagram of an integrated circuit 300 including a 3D array 302 of cross-point memory cells having switching layers (OTS switch) with programmable resistance memory layers and a buffer layer comprising silicon and carbon as described above. A row/level line decoder 304 having read, set and reset modes is coupled to, and in electrical communication with, a plurality of word lines 306 arranged in levels and along rows in the array 302. A column/level decoder 308 is in electrical communication with a plurality of bit lines 310 arranged in levels and along columns in the array 302 for reading, setting, and resetting the memory cells in the array 302. Addresses are supplied on bus 312 to row/level decoder 304 and column/level decoder 308. Sense circuitry (Sense amplifiers) and data-in structures in block 314, including voltage and/or current sources for the read, set, and reset modes are coupled to column/level decoder 308 via data bus 316. Data is supplied via a data-in line 318 from input/output ports on integrated circuit 300, or from other data sources internal or external to integrated circuit 300, to data-in structures in block 314. Other circuitry 320 may be included on integrated circuit 300, such as a general purpose processor or special purpose application circuitry, or a combination of modules providing system-on-a-chip functionality supported by array 302. Data is supplied via a data-out line 322 from the sense amplifiers in block 314 to input/output ports on integrated circuit 300, or to other data destinations internal or external to integrated circuit 300.

A controller 324 implemented in this example, using a bias arrangement state machine, controls the application of bias circuitry voltage sources and current sources 326 for the application of bias arrangements, including read, set, reset and verify voltages, and/or currents for the word lines and bit lines. The controller includes control circuitry configured for switching layers having a threshold voltage depending on the structure and composition of the memory cells, by applying a voltage to a selected memory cell so that the voltage on the switch in the select memory cell is above the threshold, and a voltage to an unselected memory cell so that the voltage on the switch in unselected memory cell is below the threshold during a read operation or other operation accessing the selected memory cell.

Controller 324 may be implemented using special-purpose logic circuitry as known in the art. In alternative embodiments, controller 324 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 324.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A device, comprising:
a first electrode;
a second electrode;
a switching layer between the first and second electrodes, the switching layer comprising an ovonic threshold switch material;
a barrier layer on a surface of the switching layer, the barrier layer comprising a composition including silicon and carbon.

2. The device of claim 1, wherein the silicon in the composition has a concentration in a range of about 4 to 18 atomic percent.

3. The device of claim 1, wherein the barrier layer is an in situ barrier layer.

4. The device of claim 1, wherein the composition of the barrier layer consists essentially of silicon and carbon.

5. The device of claim 1, including a layer of memory material in contact with the barrier layer between the first and second electrodes.

6. The device of claim 1, wherein the barrier layer is less than 50 nm thick.

7. The device of claim 1, wherein the barrier layer has a thickness in a range of 15 to 30 nm, inclusive.

8. The device of claim 1, including second barrier layer on a second surface opposite said first mentioned surface, of the switching layer.

9. The device of claim 1, including a layer of phase change memory material between the first and second electrodes.

10. The device of claim 1, wherein the ovonic threshold switch material comprises a composition including As.

11. A memory device, comprising:
a first electrode;
a second electrode;
a programmable resistance memory element between the first and second electrodes;
a switching layer in series with the memory element between the first and second electrodes, the switching layer comprising an ovonic threshold switch material; and
an in situ barrier layer between the memory element and the switching layer comprising a composition of silicon and carbon.

12. The device of claim 11, wherein the silicon in the composition has a concentration in a range of 4 to 18 atomic percent, and the switching layer comprises As.

13. The device of claim 11, wherein the barrier layer is less than 50 nm thick.

14. The device of claim 11, wherein the barrier layer has a thickness in a range of 15 to 30 nm, inclusive.

15. The device of claim 11, including a second barrier layer on a second surface opposite said first mentioned surface, of the switching layer.

16. The device of claim 11, wherein the composition of the barrier layer consists essentially of silicon and carbon.

17. A switching device, comprising:
a first electrode;
a second electrode;
an ovonic threshold switch material comprising As, between the first and second electrodes; and
a barrier layer between the first and second electrodes comprising a composition including silicon and carbon, in which the silicon in the composition has a concentration in a range of about 4 to 18 atomic percent.

18. The device of claim 17, wherein the composition of the barrier layer consists essentially of silicon and carbon.
